(19) United States
(12) Patent Application Publication
(10) Pub. No.: US 2010/0132781 A1
(43) Pub. Date: Jun. 3, 2010

(54) Back-Contacted Photovoltaic Device

(75) Inventor: Mariano Zarcone, Vanzo di San Pietro Viminario (IT)

Correspondence Address: Themis Law, 7660 Fay Ave Ste H-535, La Jolla, CA, 92037, US

(73) Assignee: XGROUP S.P.A., Vanzo di San Pietro Viminario (IT)

(21) Appl. No.: 12/664,846

(22) PCT Filed: Jun. 28, 2007
(86) PCT No.: PCT/IT2007/000461

§ 371 Date: Feb. 12, 2010

(51) Int. Cl. H01L 31/00

(52) U.S. Cl. 136/255

(57) ABSTRACT

A new photovoltaic device includes at least one front emitter made of a p- or n-doped semiconductor material, coupled with at least one rear part made of an n- or p-doped semiconductor material, wherein the front part of the emitter is connected to a plurality of contacts located at the back of the device by means of one or more diffuser elements in the shape of plates, ducts or generic elements in relief made of p- or n-doped semiconductor material, which extend from the front part of the emitter through all or part of the n- or p-doped part.

### FIELD OF THE INVENTION

The present application concerns photovoltaic devices, and more particularly concerns a new photovoltaic device of the so-called “back-contacted” type, i.e. with both the negative and the positive contacts at the back.

More precisely, the present patent concerns a new photovoltaic device with an innovative architecture, the purpose of which is to maximize the device's efficiency by means of a front surface with no contacts and a structure capable of optimizing the charge collection process.

### SUMMARY OF THE INVENTION

There are known photovoltaic devices comprising a so-called wafer, consisting of at least one p-doped semiconductor, i.e. with an excess of electronic ‘holes, coupled with at least one n-doped semiconductor, i.e. with an excess of electrons, each with their corresponding electrical contacts, wherein photon radiation on the surface of said p-doped semiconductor (adequately coated with a passivation layer) causes a charge displacement, thus generating a current in an external conductor.

At present, improving the efficiency of photovoltaic devices is the main goal of every solar cell manufacturer. In principle, improving their efficiency will coincide with a reduction in the final cost per peak Watt [Wp], though the economic issues relating to any necessary additional sophistication of the production process must always be taken into account.

As concerns the emitter contacts, several currently known technologies are capable of producing highly efficient devices, in which the emitter contacts are positioned at the back of the photovoltaic device, thus maximizing the surface area available for solar energy conversion.

Said technologies are already suitable for industrialization, but the majority of manufacturers still prefer to make photovoltaic devices using a simple technology called “screen-printing”, in order to contain the costs.

The reasons why this relatively “primitive” technology still prevails are easy to understand.

Using said screen-printing technology, the manufacturing process consists of just a few steps that require the use of straightforward, efficient production means capable of operating on “wafers” as thin as 200 μm.

Given the current shortage of silicon, the cost of PV devices can be reduced by minimizing the use of silicon. As a result, there is currently a growing tendency to reduce the thickness of the wafers, but this has its drawbacks.

In fact, because of its reduced thickness, the aluminum paste deposited on the back of the device tends to bend the wafer and thus increases the risk of it breaking in the photovoltaic cell's final manufacturing stages.

The screen-printing process is consequently proving a crucial issue in terms of reducing the thickness of the wafers being used. On the other hand, the previously-mentioned highly efficient processes have several drawbacks that, for various reasons, prevent them from gaining a dominant role on the market. The need for sophisticated production steps, combined with costly base materials that need to have a high degree of purity, make the final costs per peak Watt comparable with those achievable using the simpler screen-printing process.

The efficiency of the known photovoltaic devices is also limited by the presence of the metal emitter contacts on the front surface, which act as a shield on the surface of the solar cell, thus reducing the active surface area of the device.

To overcome this drawback, there are also known so-called “back-contacted” photovoltaic devices, in which said contacts are not provided on the front surface.

Among the new technological solutions, said back-contacted photovoltaic devices are particularly attractive and interesting. The aesthetic features and efficiency of these devices are better than those of the classic alternatives, and the cells are also easier to assemble.

Several industrial processes that use this approach are now known.

According to one of said processes, for instance, the interface of separation between the p-n charges is located on the back of the device together with the interdigital collection contacts. The efficiency of such devices is the highest available on the market, but the sophisticated steps involved in their manufacture and the special base materials needed (FZ Si) make the procedure rather complex and costly.

To overcome said drawbacks, additional technologies have been developed, known respectively by the names of Metal Wrap Through (MWT) and Emitter Wrap Through (EWT). Both these methods involve making several holes in the thickness of the wafers with the aid of laser technology.

In detail, the MWT method involves said holes being filled with the same type of metal paste as is used for the front contacts, so as to create a plurality of ducts connecting the front of the cell with the collection contacts located on the back of the cell.

The EWT method, on the other hand, involves coating the inside walls of said holes with a layer of emitter so as to connect the surface emitter with the metallization on the back.

### SUMMARY OF THE INVENTION

The object of the present invention is a new type of photovoltaic device of the so-called “back-contacted” type.

The main object of the present invention is to achieve a greater efficiency due to the increase in the surface area globally active in the solar energy process conversion, and to an optimized charge collection process.

Another important object of the present invention is to accelerate and simplify the procedures involved in the manufacture of a back-contacted photovoltaic device, also reducing the cost per peak Watt as a consequence.

These and other direct and complementary objects are achieved by a new type of back-contacted photovoltaic device comprising at least one front emitter made of a semiconductor material that is p-doped, e.g. with boron, coupled with at least one rear part made of a semiconductor material that is n-doped, e.g. with phosphorus, wherein the front part of said emitter is connected to a plurality of metal contacts located on the rear of the device, by means of one or more emitter plates, ducts or generic elements in relief, made of a p-doped semiconductor material, passing through the thickness of said interposed p-doped part.

In detail, the new device has a substantially stratified structure, wherein said emitter comprises an extended front part made of a p-doped semiconductor material, the exposed surface of which undergoes electronic passivation, preferably by means of the deposition of at least one layer of material typically with a structure Si₃N₄/SiO₂, in thicknesses of 78 and 4 nm, respectively, for instance.

Said emitter also comprises one or more projecting parts connected to said extended front part, in the form of plates, ducts or generic elements in relief, hereinafter called diffuser elements. which are also made of a p-doped semiconductor material and pass through the full thickness of the interposed part made of n-doped semiconductor material, and the metal contacts of the emitter are located on the lower edges of said diffuser elements, which face towards the rear of the device.

In addition to said emitter contacts, on the rear of the device there are also the interdigital collection contacts for the photogenerated charge carriers, generated by the absorption of the photons of the incident luminous beam, and said collection contacts are connected to said n-doped part.

The new device consequently has no holes on said extended front part; instead, it only has localized diffuser elements that extend from the front part to the rear part of the device, passing through said n-doped part and thus providing the connection between the front p-n interface and the back contacts.

Some grooves are also provided on the rear of the device, around the contact areas between said p-doped diffuser elements and the n-doped part, to guarantee a better isolation between the two and between the corresponding contacts.

In the preferred embodiment, said back contacts of said emitter are printed with a silver/aluminum paste on the lower edges of said diffuser elements, while said back contacts of the n-doped part are made with silver paste.

Said diffuser elements passing through the thickness of the n-doped part, which is approximately 200 μm thick, may be obtained, for instance, by laser-assisted diffusion.

In the preferred embodiment, said emitter comprises a plurality of diffuser elements in the form of plates substantially orthogonal to said extended front part, preferably parallel to one another, lying side by side, perpendicular to a further side wall extending orthogonal to said flat front part.

The diffuser channels can also be a series of adjacent cylinders with a base around 100 μm in diameter.

The back contacts are printed on the lower edge of each of said plates, facing towards the rear of the device, substantially creating a circuit converging towards said collector side wall.

Said n-doped part has a shape that is complementary to said emitter and consequently comprises a plurality of parallel plates, each interposed between and in contact with two of said emitter plates, and lying likewise side by side and perpendicular to a side wall.

Back contacts are printed on the lower edge of each of said plates of the n-doped part and substantially create a circuit that converges towards said side collector wall.

The invention thus achieves a high efficiency due to the absence of any metallization on the front surface, and the consequent increase in its useful surface area.

Moreover, there is a better chance of separating the photogenerated carriers due to the contributions of the walls of the diffuser elements lying substantially orthogonal to said front part, which increase the effective surface area of the interface between the p-doped parts and the n-doped parts.

As for the manufacture of said diffuser elements using laser technology, it has been demonstrated that a suitable laser source is capable of locally increasing the temperature of the silicon until it becomes sublimated without excessively damaging the cross-linking of the crystals around the radiated area. It is consequently considered feasible to obtain suitably doped areas, such as those needed to realize the new device, by means of a diffusion of the impurities in the liquid phase, achieved by melting said areas with the aid of a laser. The object is to obtain diffuser elements as deep as the full thickness of the p-doped part by means of a rapid, reliable process, that can be done in milliseconds.

The use of laser sources to produce said diffuser elements shall not be considered as limiting, however, but simply as one of the possible technical solutions for their manufacture.

The device may also be made, and conveniently employed, switching the basic doping from the n type to the p type, and consequently creating the emitter and the connection channels or plates with n type doping.

### BRIEF DESCRIPTION OF THE DRAWINGS

The characteristics of the new photovoltaic device will become more apparent from the following description with reference to the attached drawings, which are provided as a non-limiting example.

FIG. 1 shows the architecture of the new device, which—in the vertical sense—consists of a series of layers: a layer of composite front surface passivation (1.1, 1.2) with Si₃N₄/SiO₂, an extended front part (2.1) of the emitter (2) made of silicon p-doped with boron, a rear part (3) made of silicon n-doped with phosphorus, with the back contacts (4) of the emitter (2) made of aluminum/silver and the silver collector contacts (5) of the n-doped part (3).

FIGS. 2 and 3 separately show in detail the p-doped emitter (2) with its corresponding contacts (4), and the n-doped part (3) with its corresponding contacts (5).

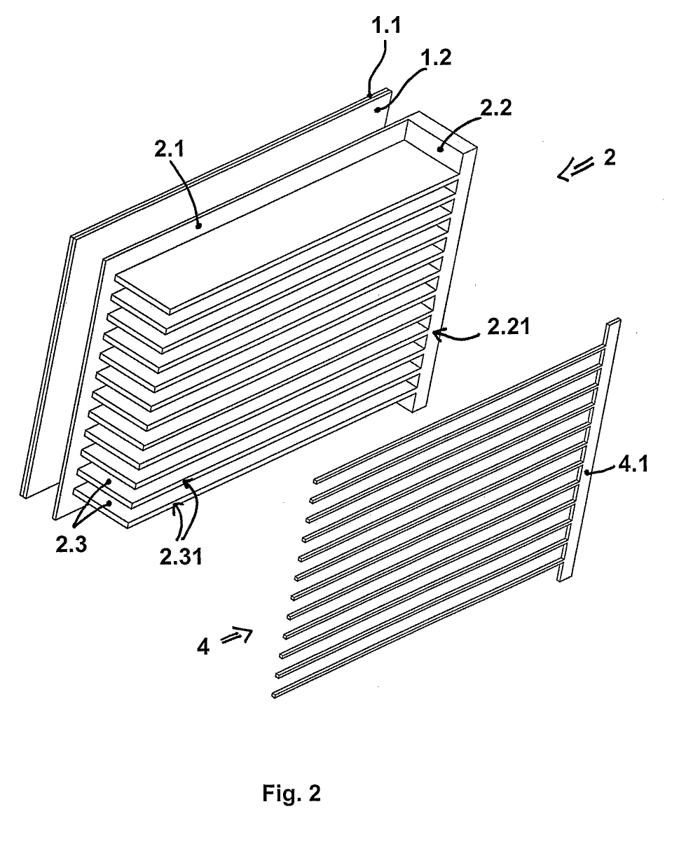

FIG. 4 shows the rear of the device without the back contacts (4, 5).

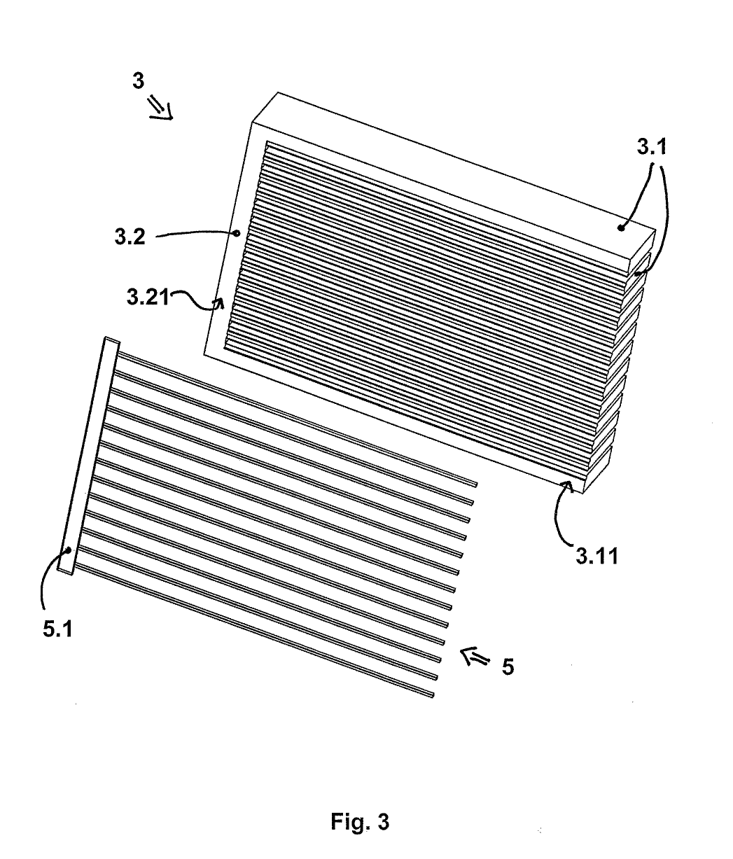

FIG. 5 shows a detail of the back contacts (4, 5) of the emitter (2) and of the n-doped part (3), in which the interposed grooves (6) are also visible.

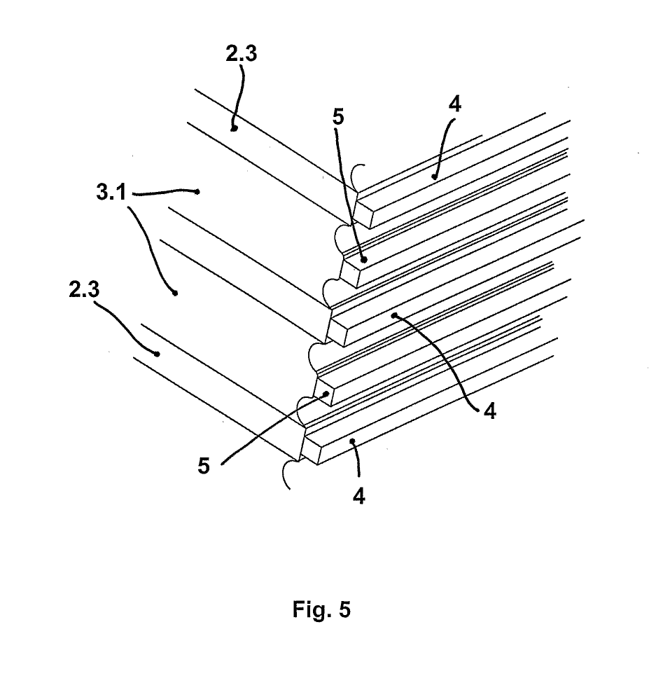

FIG. 6 shows a cross section of the device.

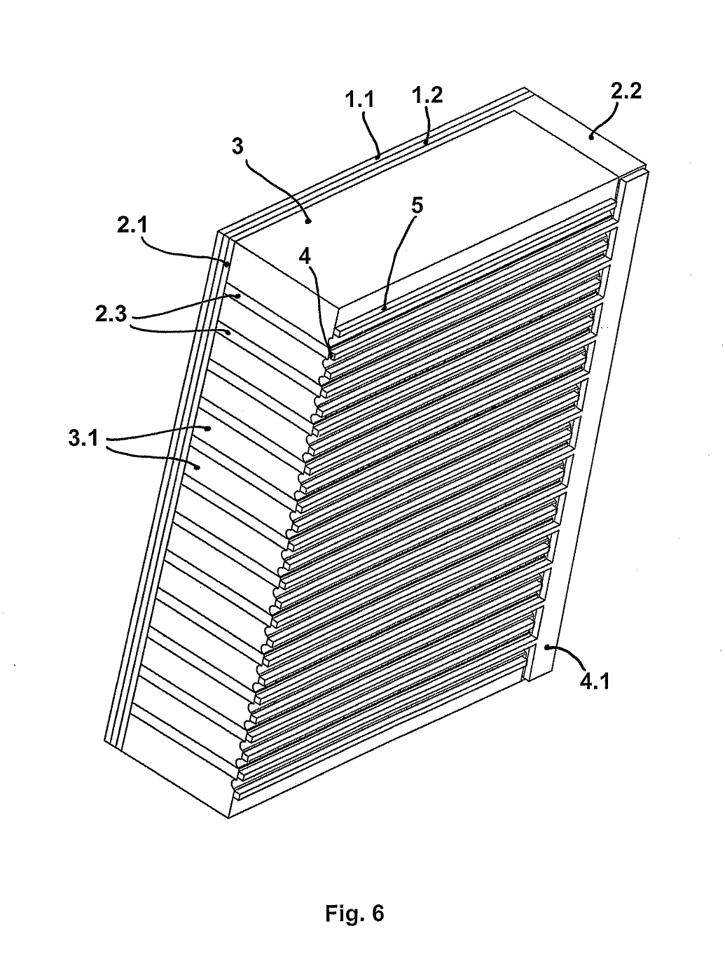

### DETAILED DESCRIPTION OF THE INVENTION

The new photovoltaic device is of the back-contacted type, i.e. it has the positive contacts (4) and the negative contacts (5) located on the rear of the device.

The new device comprises a front emitter (2) made of a p- or n-doped semiconductor material, coupled with at least one rear part (3) made of an n- or p-doped semiconductor material, the front part (2.1) of said emitter (2) being connected to a plurality of metal contacts (4) located on the rear of the device by means of one or more plates (2.3), ducts or generic elements in relief, made of a p-or n-doped semiconductor material, that pass entirely or partially through the thickness of said n- or p-doped interposed part (3).

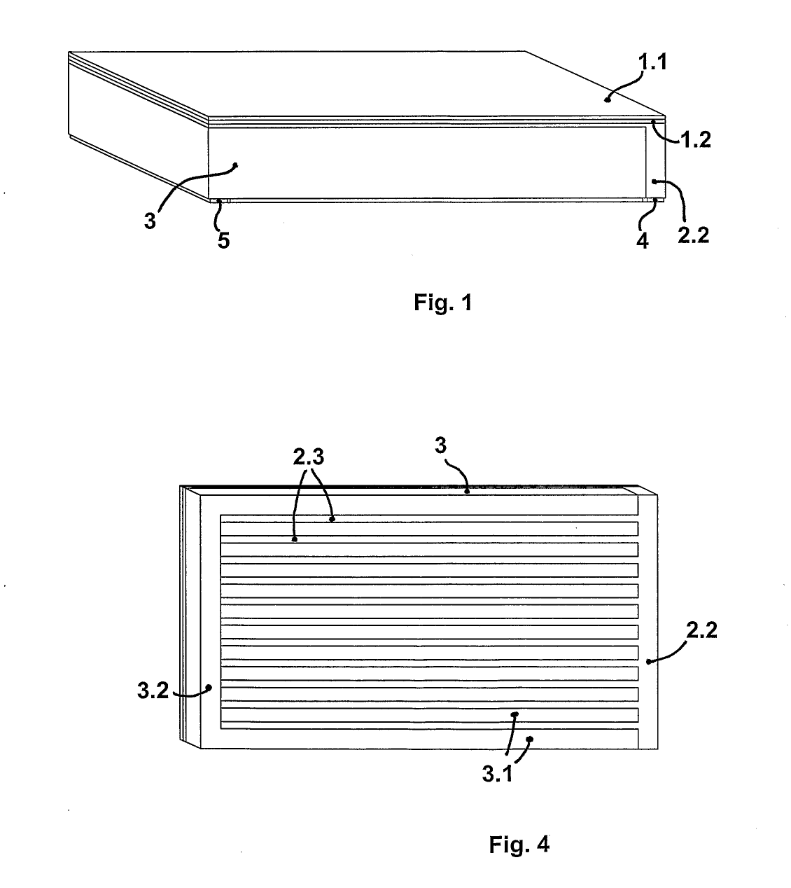

As shown in FIG. 1, the new device has a substantially stratified design, wherein said emitter (2) comprises an extended front part (2.1), the exposed surface of which undergoes electronic passivation, preferably by means of the deposition of at least one composite layer (1.2, 1.2) typically with a Si3N4/SiO2 structure.

Connected to said extended front part (2.1), said emitter (2) also comprises one or more projecting parts in the form of plates, ducts or generic elements in relief, hereinafter called diffuser elements (2.3), passing entirely or partially through the interposed n- or p-doped part (3), with the lower edges (2.31) of said diffuser elements (2.3) supporting the metal contacts (4) of the emitter (2).

The interdigital collection contacts (5) of the photogenerated charge carriers, connected to said n- or p-doped part (3) are also located on the rear of the device. Several grooves (6) are also provided on the rear of the device, around the contact areas between said p- or n-doped diffuser elements (2.3) and the n- or p-doped parts (3.1) in order to provide a better isolation between them and between their corresponding contacts (4, 5).

In the preferred embodiment, said diffuser elements (2.3) are in the form of plates substantially orthogonal to said extended front part (2.1), preferably parallel to one another and lying side by side, perpendicular to a further side wall (2.2) that extends orthogonal to said flat front part (2.1).

Said diffuser elements may also be a series of adjacent cylinders with a base having a diameter of around 1001.t.

Back contacts (4) are printed on the lower edge (2.31) of each of said plates (2.3) facing towards the rear of the device, substantially creating a circuit that converges towards said side collector wall (2.2).

Said n- or p-doped part (3) has a shape complementary to that of the emitter (2) and consequently comprises a plurality of parallel plates (3.1), each interposed between and in contact with two of said plates (2.3) of the emitter (2), and lying side by side. perpendicular to a side wall (3.2).

Back contacts (5) are printed on the lower edge (3.11) of each of said plates (3.1) of the n- or p-doped part, substantially creating a circuit that converges towards said side collector wall (3.2).

Thus, with reference to the above description and to the attached drawings, the following claims are advanced.

What is claimed is:

1. A photovoltaic device comprising:
at least one front emitter made of a p- or n-doped semiconductor material; and
at least one rear part made of an n- or p-doped semiconductor material, the at least one rear part being electrically coupled to the at least one front emitter,
wherein a front part of said at least one front emitter is electrically connected to a plurality of contacts located at the rear of the device via one or more diffuser elements in the shape of plates, ducts, or generic elements in relief, the one or more diffuser elements being made of p- or n-doped semiconductor material and extending from said front part of the at least one front emitter through all or part of said rear part.

2. The photovoltaic device according to claim 1, further comprising one or more grooves provided on a rear surface of the device, in the vicinity of, or along one or more coupling areas between said p- or n-doped diffuser elements and said rear part, to partially or totally isolate the two.

3. The photovoltaic device according to claim 1,
wherein said front part of said at least one front emitter is extended, a plurality of said diffuser elements in the shape of parallel plates extending substantially orthogonally thereto and lying substantially side by side and perpendicular to a side wall, and
wherein said rear part has a complementary shape thereto and comprises a plurality of parallel plates, each interposed between two plates of the at least one emitter, and perpendicular to a further side wall.

4. The photovoltaic device according to claim 3,
wherein said back contacts of the at least one front emitter are applied along lower edges of corresponding plates of the at least one front emitter and are connected to contacts applied along a lower edge of said side wall of the at least one front emitter, and
wherein the back collector contacts of the at least one rear part are applied along lower edges of corresponding plates of the at least one rear part and connected to the contacts applied along lower edges of said further side wall of the at least one rear part, so that said contacts applied along the lower edge of said side wall and of the at least one front emitter and of the at least one rear part respectively provide circuits that do not intersect one another.

5. The photovoltaic device according to claim 1, wherein the contacts are metal contacts.
